(19) United States
(12) Patent Application Publication
(10) Pub. No.: US 2007/0063266 A1
(43) Pub. Date: Mar. 22, 2007

(54) Semiconductor device and method for manufacturing the same

(76) Inventors: Katsuaki Natori, Yokohama-shi (JP); Masayuki Tanaka, Yokohama-shi (JP); Hirokazu Ishida, Yokohama-shi (JP); Katsuyuki Sekine, Yokohama-shi (JP); Masumi Matsuzaki, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/520,698

(22) Filed: Sep. 14, 2006

(30) Foreign Application Priority Data
Sep. 22, 2005 (JP) P2005-276786

(51) Int. Cl. H01L 29/792

(52) U.S. Cl. 257/324

(57) ABSTRACT

A semiconductor device includes a semiconductor region; a first high dielectric constant insulating film provided on the semiconductor region, the first high dielectric constant insulating film being a film other than alumina; a second high dielectric constant insulating film provided on the first high dielectric constant insulating film, the second high dielectric constant insulating film being an alumina film; and a conductive layer provided on the second high dielectric constant insulating film.

### CROSS REFERENCE TO RELATED APPLICATIONS AND INCORPORATION BY REFERENCE

This application is based upon and claims the benefit of priority from prior Japanese Patent Application P2005-276786 filed on Sep. 22, 2005; the entire contents of which are incorporated by reference herein.

### BACKGROUND OF THE INVENTION

1. Field of the Invention

The present invention relates to a semiconductor device having a high dielectric constant insulating film and a method for manufacturing a semiconductor device.

2. Description of the Related Art

To assist in providing a high-density large-scale integrated circuit (LSI), a gate insulating film and a capacitor insulating film have become thinner in recent years. In order to avoid an increase in a leak current due to thinning of the gate insulating film and the capacitor insulating film, measures have been taken to change a structure of a semiconductor device to a three-dimensional structure and the like. Moreover, there is a proposal to increase a physical film thickness by use of a high dielectric constant insulating film to suppress the increase of the leak current (refer to Japanese Patent Laid-Open Official Gazette No. 2005-109231).

Particularly, in a non-volatile semiconductor storage device, such as an electrically erasable and programmable read only memory (EEPROM), there has been an attempt to increase a dielectric constant of an inter-polysilicon dielectric (IPD) film, which is formed between a charge storage layer and a control electrode, by using a silicon oxide/silicon nitride/silicon oxide stack (ONO) film, for example. Concurrently, there is also an attempt to use a three-dimensional structure in order to increase the area of the IPD film. However, as the distance between adjacent memory cells in the semiconductor storage device is shortened, inter-cell interference, which is interference between the adjacent cells, is significantly increased. Accordingly, device characteristics are deteriorated. Thus, it is difficult to increase the area of the IPD film by using the three-dimensional structure.

For this reason, in order to achieve a next-generation non-volatile semiconductor storage device, it is necessary to use an insulating film having a higher dielectric constant as an IPD film. By using the high dielectric constant insulating film, capacitance of the IPD film can be increased without increasing the area of the IPD film. Thus, it is no longer necessary to use the three-dimensional structure, and manufacturing processes can be simplified. As a result, performance of the memory cells is improved, and a manufacturing method for a semiconductor storage device is simplified. Hence, it is possible to increase the manufacturing yield of a semiconductor storage device.

As a high dielectric constant insulating film, a composite oxide film, such as hafnium aluminate (HfAlO), is deposited by chemical vapor deposition (CVD), such as atomic layer deposition (ALD). CVD may provide a uniform film thickness, mass productivity, low damage rates and the like, for the composite oxide film. However, when the high dielectric constant insulating film is used in an EEPROM, as an IPD film, there is a problem that a leak current cannot be sufficiently suppressed due to a high electric field applied to the IPD film.

### SUMMARY OF THE INVENTION

A first aspect of the present invention inheres in a semiconductor device including a semiconductor region; a first high dielectric constant insulating film provided on the semiconductor region, the first high dielectric constant insulating film being a film other than alumina; a second high dielectric constant insulating film provided on the first high dielectric constant insulating film, the second high dielectric constant insulating film being an alumina film; and a conductive layer provided on the second high dielectric constant insulating film.

A second aspect of the present invention inheres in a method for manufacturing a semiconductor device including depositing a first high dielectric constant insulating film on a semiconductor region, the first high dielectric constant insulating film being a film other than alumina; depositing a second high dielectric constant insulating film on the first high dielectric constant insulating film, the second high dielectric constant insulating film being an alumina film; anneal the second high dielectric constant insulating film; and depositing a conductive layer on the second high dielectric constant insulating film in a reducing atmosphere.

### BRIEF DESCRIPTION OF DRAWINGS

FIG. 1 is a plan view showing an example of a semiconductor device according to a first embodiment of the present invention;

FIG. 2 is a cross sectional view taken on line II-II of the semiconductor device shown in FIG. 1;

FIG. 3 is a cross sectional view taken on line III-III of the semiconductor device shown in FIG. 1;

FIG. 4 is a top view during manufacturing showing an example of the semiconductor device according to the first embodiment of the present invention;

FIGS. 5 to 10 are cross sectional views taken on line V-V of the semiconductor device shown in FIG. 4, showing an example of a manufacturing method of the semiconductor device according to the first embodiment of the present invention;

FIG. 11 is a cross sectional view taken on line XI-XI of the semiconductor device shown in FIG. 10, showing an example of a manufacturing method of the semiconductor device according to the first embodiment of the present invention;

FIG. 12 is a diagram showing an example of dependance of a leak current density of the IPD film on an Al₂O₃ thickness of the semiconductor device according to the first embodiment of the present invention;

FIG. 13 is a cross sectional view showing an example of a semiconductor device according to a second embodiment of the present invention; and

FIG. 14 is a cross sectional view showing an example of a semiconductor device according to a third embodiment of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

(First Embodiment)

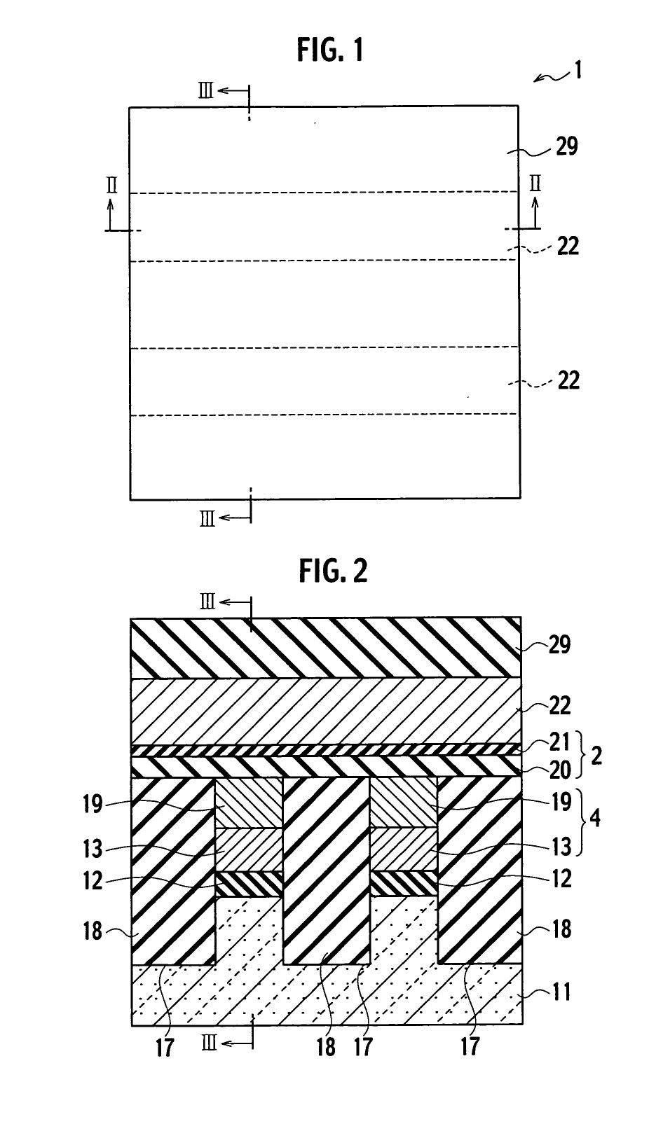

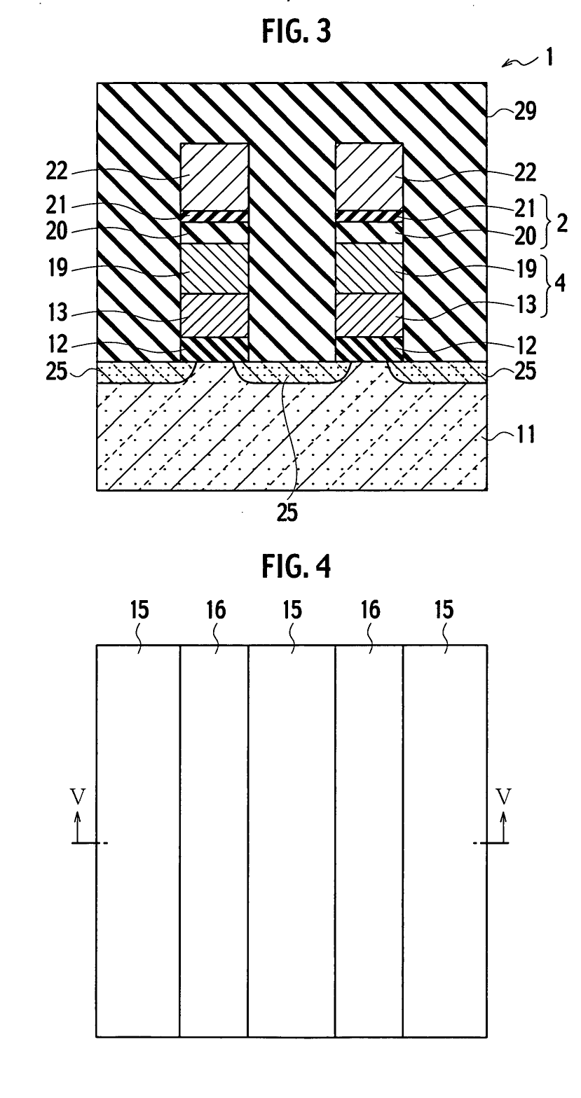

As shown in FIGS. 1 to 3, a semiconductor device according to a first embodiment of the present invention is a non-volatile semiconductor storage device 1, such as a NAND-type electrically rewritable non-volatile memory (EEPROM). The non-volatile semiconductor storage device 1 includes a conductive film (a semiconductor region) 19, a first high dielectric constant insulating film 20, a second high dielectric constant insulating film (an alumina (Al₂O₃) film) 21, and a conductive layer (a control gate electrode) 22. In the first embodiment, the first and second high dielectric constant insulating films 20, 21 are used for an inter-electrode insulating film (an IPD film) 2 between a floating gate electrode 4 and the control gate electrode 22. The floating gate 4 serves as a charge storage layer.

The first high dielectric constant insulating film 20 is provided directly on the conductive film 19, and contains a metal element other than aluminum (Al). The Al₂O₃ film 21 is provided on the first high dielectric constant insulating film 20. The conductive layer 22 is provided on the Al₂O₃ film 21. Consequently, it is possible to reduce a leak current flowing between the semiconductor region 19 and the conductive layer 22 through the first high dielectric constant insulating film 20.

The non-volatile semiconductor storage device 1 includes a semiconductor substrate 11. Isolation trenches 17 are formed in the semiconductor substrate 11. Isolation insulating films 18 are buried in the isolation trenches 17. A plurality of element regions are defined, and isolated from each other, by the isolation insulating films 18.

In each of the element regions, an insulating layer 12, which is a first gate insulating film, is provided on the semiconductor substrate 11. The floating gate electrode 4 has a laminated structure which includes the conductive films 13 and 19 and is provided on the insulating layer 12. Each of the conductive films 13 and 19 is a heavily-doped semiconductor film.

The IPD film 2, which is a second gate insulating film, is provided on the conductive film 19. The IPD film 2 has a laminated structure that includes the first high dielectric constant insulating film 20 as a lower film and the Al₂O₃ film 21 as an upper film. For the first high dielectric constant insulating film 20, a composite oxide containing Al may be used. Specifically, hafnium aluminate (HfAlO), zirconium aluminate (ZrAlO), lanthanum aluminate (LaAlO) or the like is used as the composite oxide containing aluminum.

The conductive layer 22, which is a control gate electrode, is provided on the Al₂O₃ film 21. An insulating layer 29, which serves as a passivation film, is provided on the conductive layer 22. The insulating layer 29 is also disposed on source/drain regions 25. The source/drain regions 25 are provided in the semiconductor substrate 11 from a surface of the semiconductor substrate 11.

Next, a description will be given with respect to a method for manufacturing the non-volatile semiconductor storage device 1 according to the first embodiment.

As shown in FIGS. 4 and 5, a first insulating layer 12 is formed with a thickness in a range of about 1 nm to 15 nm on a p-type silicon (Si) substrate 11, or a p-type well 11 formed in an n-type Si substrate. The first insulating layer 12 is formed by oxidization and nitridation of a surface of the substrate 11. Doped polysilicon (poly-Si) is deposited on the first insulating layer 12 by chemical vapor deposition (CVD) and the like. Thus, a first conductive film 13 is formed with a thickness in a range of about 10 nm to about 200 nm. The first conductive film 13 is a part of the floating gate electrode, and serves as a charge storage layer.

On the first conductive film 13, a silicon nitride (Si₃N₄) film 14 is deposited with a thickness in a range of about 50 nm to about 200 nm by CVD and the like. Furthermore, on the Si₃N₄ film 14, a silicon oxide (SiO₂) film 15 is deposited with a thickness in a range of about 50 nm to about 400 nm by CVD and the like. A resist film is formed by coating a photoresist onto the SiO₂ film 15. The resist film is patterned by photolithography and the like, to form a resist mask 16.

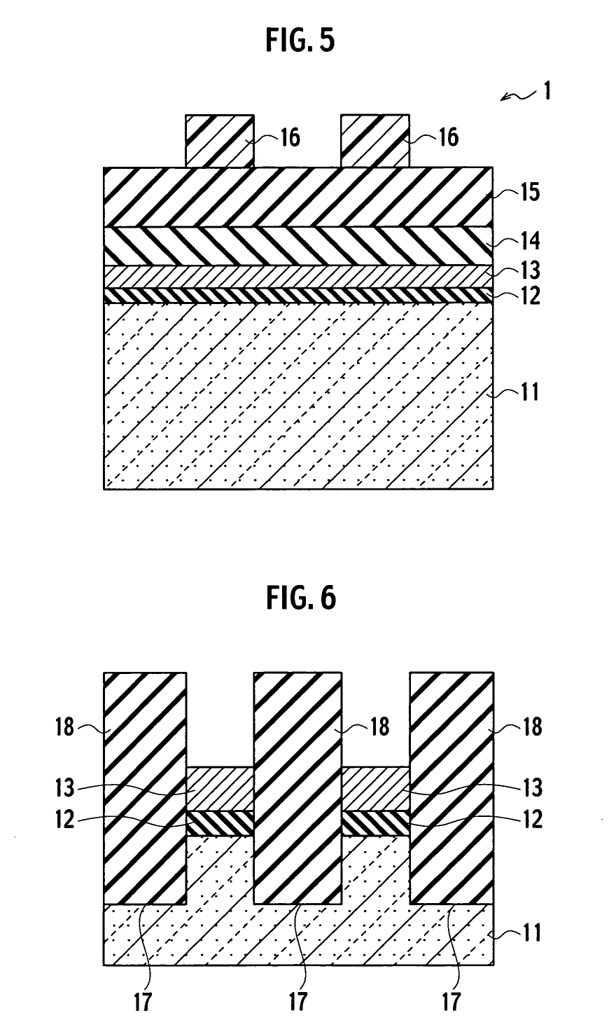

As shown in FIG. 6, the SiO₂ film 15 is selectively removed by reactive ion etching (RIE) and the like, using the resist mask 16 as a mask and the Si₃N₄ film 14 as a stopper. After etching of the SiO₂ film 15, the resist mask 16 is removed.

The Si₃N₄ film 14 is etched by RIE and the like, using the SiO₂ film 15 as a mask. Subsequently, the first conductive film 13, the first insulating layer 12 and the substrate 11 are selectively removed by RIE and the like, to form isolation trenches 17. After etching, a high-temperature oxidation process is performed for eliminating damages caused by RIE and the like, on side faces of the first conductive film 13, the first insulating layer 12 and the silicon substrate 11.

An insulating film, such as SiO₂, is deposited with a thickness in a range of about 200 nm to about 1500 nm by CVD and the like, to fill in the isolation trenches 17. The deposited insulating film is annealed at a high temperature in a nitrogen atmosphere or an oxygen atmosphere so as to densify the insulating film. The annealed insulating film is planarized by chemical mechanical polishing (CMP) and the like, using the Si₃N₄ film 14 as a stopper, to form isolation insulating films 18. Thus, the annealed insulating film on the Si₃N₄ film 14 is removed. Subsequently, the Si₃N₄ film 14 is removed by hot phosphoric acid (H₃PO₄) and the like, which provides a significant etching selectivity of Si₃N₄ to SiO₂. Thus, a cross sectional structure shown in FIG. 6 is achieved.

In the first embodiment, the laminated film, which includes the Si₃N₄ film 14 and the SiO₂ film 15, is used as a mask to form the isolation trench 17. However, by providing an appropriate thickness of the Si₃N₄ film 14 or the SiO₂ film 15, and a RIE condition, a single layer Si₃N₄ film or a single layer SiO₂ film may be used as a mask. Moreover, a single layer film or a multilayer film other than Si₃N₄ and SiO₂, can be used as a mask, as long as the film is made of a material which can be selectively etched over SiO₂.

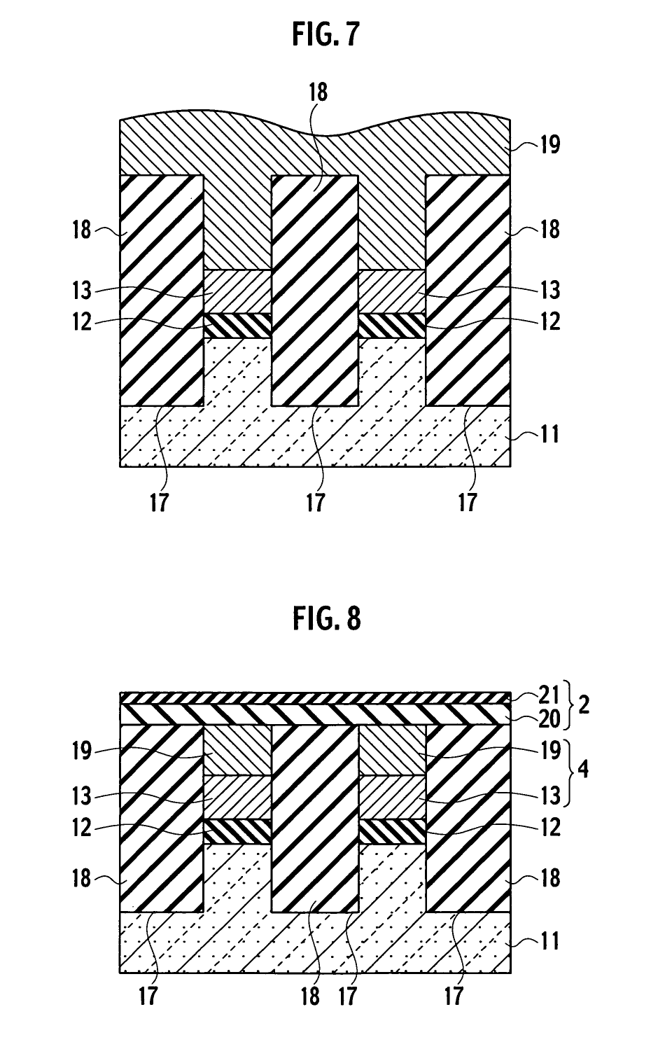

As shown in FIG. 7, on the first conductive film 13, a second conductive film 19, which is excellent in step coverage, is deposited by CVD and the like, so as to fill in trenches created after removing the Si₃N₄ film 14. A doped poly-Si film can be used for the second conductive film 19. The second conductive film 19 is planarized by CMP and the like, using the isolation insulating films 18 as stoppers to remove the second conductive film 19 deposited on the isolation insulating films 18. A laminated structure of the first and second conductive films 13 and 19 is used for a floating gate electrode.

As shown in FIG. 8, a first high dielectric constant insulating film 20 is deposited on the planarized conductive film 19 and the isolation insulating films 18. The first high dielectric constant insulating film 20 has a dielectric constant higher than that of the SiO₂ film. It is desirable that the first high dielectric constant insulating film 20 is a film other than Al₂O₃ and having a dielectric constant higher than about 3.8 to about 4 of a SiO₂ film, and particularly, higher than a dielectric constant of about 5 to about 5.5 of an ONO film. In the first embodiment, a HfAlO film, which is a composite oxide film containing hafnium (Hf) and Al, is used for the first high dielectric constant insulating film 20. A method of depositing a HfAlO film by ALD will be described in detail below.

Deposition of the HfAlO high dielectric constant insulating film 20 onto the conductive film 19 is achieved by the sequential and repeated execution of deposition sequences. Each sequence includes: sequentially and repeatedly executing a plurality of cycles, each cycle includes introducing a hafnium (Hf) compound gas so as to adsorb first reactive species on a surface of the conductive film 19, purging the unreacted Hf compound gas, introducing an oxidant gas to the surface of the conductive film 19 so as to react the oxidant gas with the adsorbed first reactive species, and purging the unreacted oxidant gas; and sequentially and repeatedly executing a cycle which includes introducing an Al compound so as to adsorb second reactive species on the processing surface of the conductive film 19, purging the unreacted Al compound gas, introducing the oxidant gas to the processing surface of the conductive film 19 so as to react the oxidant gas with the adsorbed second reactive species, and purging the unreacted oxidant gas. The first reactive species are molecules of the Hf compound or decomposed molecules of the Hf compound, and the second reactive species are molecules of the Al compound or decomposed molecules of the Al compound.

Specifically, the processed Si substrate 11 is transported into a vacuum chamber of an ALD apparatus that is maintained at a pressure of about 40 Pa. The Si substrate 11 is heated to a temperature of about 290° C. A source gas including an Al compound, such as trimethylaluminum (TMA), and an oxidant gas, such as ozone (O₃), are alternately fed to a surface of the Si substrate 11 so as to deposit an aluminum oxide (AlO) film, in which an Al atomic layer and an oxygen (O) atomic layer are respectively formed. Moreover, a source gas including a Hf compound, such as tetrakis ethylmethylamino hafnium (TEMAH), and the oxidant gas, such as O3, are alternately fed to the surface of the Si substrate 11 so as to deposit a hafnium oxide (HfO) film, in which a Hf atomic layer and an O atomic layer are respectively formed. The AlO film and the HfO film are stacked in layers, and deposition of the AlO film and the HfO film is repeated to provide a desired number of layers, respectively. Thus, a HfAlO film, which has a required composition ratio of Al to Hf and a required thickness, is deposited.

The flow rate of a carrier gas of TMA is about 200 sccm, and a carrier gas of TEMAH is about 500 sccm, respectively. The flow rate of O₃ is about five slm, and the concentration of O₃ is about 250 g/m³. Moreover, the time for feeding each source gas to the surface of the Si substrate 11 is about one second for TMA, about two seconds for TEMAH, and about three seconds for O₃. Furthermore, a nitrogen (N₂) gas for purging the atmosphere inside the vacuum chamber is introduced with a flow rate of about 5 slm for about two to about three seconds between alternate feeding of TMA and O₃, and between alternate feeding of TEMAH and O₃.

For a specific number of alternate feeding cycles, a sequence, in which one alternate feeding cycle of TMA and O₃ is performed every thirteen alternate feeding cycles of TEMAH and O₃, is repeated fifteen times. Accordingly, a HfAlO high dielectric constant insulating film 20 with a thickness of about twenty nm is deposited. Here, by increasing or decreasing the number of alternate feeding cycles of TEMAH and O₃, the composition ratio of Al to Hf can be changed. Moreover, by increasing or decreasing the number of repeating sequences, the thickness of the HfAlO high dielectric constant insulating film 20 can be adjusted.

Thereafter, first post deposition anneal (PDA) is performed at a temperature of about 500° C. to about 1200° C., for example, for about ten minutes to about two hours by furnace annealing, or for about one second to about thirty minutes by lamp annealing. The HfAlO high dielectric constant insulating film 20 is densified by the first PDA to improve film quality of the first high dielectric constant insulating film 20. Note that the first PDA for the HfAlO high dielectric constant insulating film 20 can be omitted, if a second PDA is performed for an Al₂O₃ film, which will be described later. However, since the HfAlO high dielectric constant insulating film 20 is densified by the first PDA, diffusion of the Al₂O₃ film into the HfAlO high dielectric constant insulating film 20 may be prevented during the second PDA. Accordingly, it is possible to cover the first high dielectric constant insulating film 20 by Al atoms, even with a thinner Al₂O₃ film, so as not to reveal a Hf atom, when depositing a conductive layer 22.

If the first PDA is omitted, an Al₂O₃ film is deposited for the second high dielectric constant insulating film 21 on the first high dielectric constant insulating film 20 immediately after depositing the first high dielectric constant insulating film 20. A method of depositing the Al₂O₃ film by ALD will be described in detail below.

The Al₂O₃ film deposition onto the first high dielectric constant insulating film 20 is achieved by the sequential and repeated execution of processing cycles. Each cycle includes introducing an Al compound gas so as to adsorb reactive species on a surface of the first high dielectric constant insulating film 20, purging the unreacted Al compound gas, introducing an oxidant gas to the surface of the first high dielectric constant insulating film 20 so as to react the oxidant gas with the adsorbed reactive species, and purging the unreacted oxidant gas. The reactive species are molecules of the aluminum compound or decomposed molecules of the aluminum compound.

Specifically, leaving the Si substrate 11 in the vacuum chamber, the pressure in the vacuum chamber is maintained at about 40 Pa, and the temperature of the Si substrate 11 is maintained at about 290° C. By alternate feeding of TMA and O₃ to the surface of the Si substrate 11, an AlO film, in which an Al atomic layer and an O atomic layer are respectively formed, can be deposited. The AlO film is stacked in layers, and deposition of the AlO film is repeated to provide a desired number of layers. Thus, an Al₂O₃ film, which has a required thickness, is deposited directly on the first high dielectric constant insulating film 20.

In addition, if the first PDA for the HfAlO film 20 is omitted, the Al₂O₃ film 21 is deposited immediately after deposition of the first high dielectric constant insulating film 20. After the first high dielectric constant insulating film 20, which contains Hf and Al, is deposited on the first conductive layer 19 by ALD, the source gases, such as TMA and O₃, are alternately fed subsequently by ALD while maintaining the pressure in the vacuum chamber and the temperature of the Si substrate 11. The Al source gas of TMA and the oxidant source gas of O₃ are commonly used for both ALD for the HfAlO high dielectric constant insulating film 20 and the Al₂O₃ film 21. Thus, an increase in manufacturing costs can be minimized, and damage, such as incorporation of unexpected impurities into the HfAlO film 20 and the Al₂O₃ film 21, may be suppressed.

The flow rate of a carrier gas of TMA is about 200 sccm, the flow rate of O₃ is about 5 slm, and the concentration of O₃ is about 250 g/m³. Moreover, the time for feeding the source gas to the substrate 11 is about one second for TMA and about three seconds for O₃. Furthermore, a N₂ gas for purging the atmosphere inside of the vacuum chamber is introduced with a flow late of about five slm for about two to about three seconds between alternate feeding of TMA and O₃.

As shown in FIG. 12, by repeating alternate feeding of TMA and O₃ for ten cycles, the Al₂O₃ film 21 with a thickness of about 0.8 nm can be deposited. Moreover, a plurality of non-volatile semiconductor storage devices having a different thickness of the Al₂O₃ film 21 are manufactured by changing only the number of alternate feeding cycles of TMA and O₃. To be more specific, the non-volatile semiconductor storage devices are manufactured with three, five, ten, fifteen, and twenty alternate feeding cycles, where the corresponding thicknesses of the Al₂O₃ films are about 0.2 nm, about 0.4 nm, about 0.8 nm, about 1.2 nm and about 1.6 nm, respectively. Moreover, as a comparative example, a non-volatile semiconductor storage device, in which only the Al₂O₃ film 21 is omitted, is also manufactured.

As a second PDA for the Al₂O₃ film 21, the Al₂O₃ film 21 is annealed at a temperature of about 500° C. to about 1200° C., for example, for about ten minutes to about two hours by furnace annealing, or for about one second to about thirty minutes by lamp annealing. The Al₂O₃ film 21 is densified by the second PDA to improve film quality of the Al₂O₃ film 21. Moreover, when the first PDA for the HfAlO film 20 is omitted, the first high dielectric constant insulating film 20 is also annealed by the second PDA for the Al₂O₃ film 21. Thus, the HfAlO film 20 is also densified to improve film quality of the first high dielectric constant insulating film 20. Since an exposed surface of the Si substrate 11 is covered with the Al₂O₃ film 21, Hf atoms of the HfAlO film 20 are not exposed on the exposed surface of the Si substrate 11 at deposition of the conductive layer 22.

Accordingly, an IPD film 2, which serves as a second gate insulating film, is formed. The IPD film 2 has a laminated structure including the first high dielectric constant insulating film 20 as a lower film and the Al₂O₃ film 21 as an upper film.

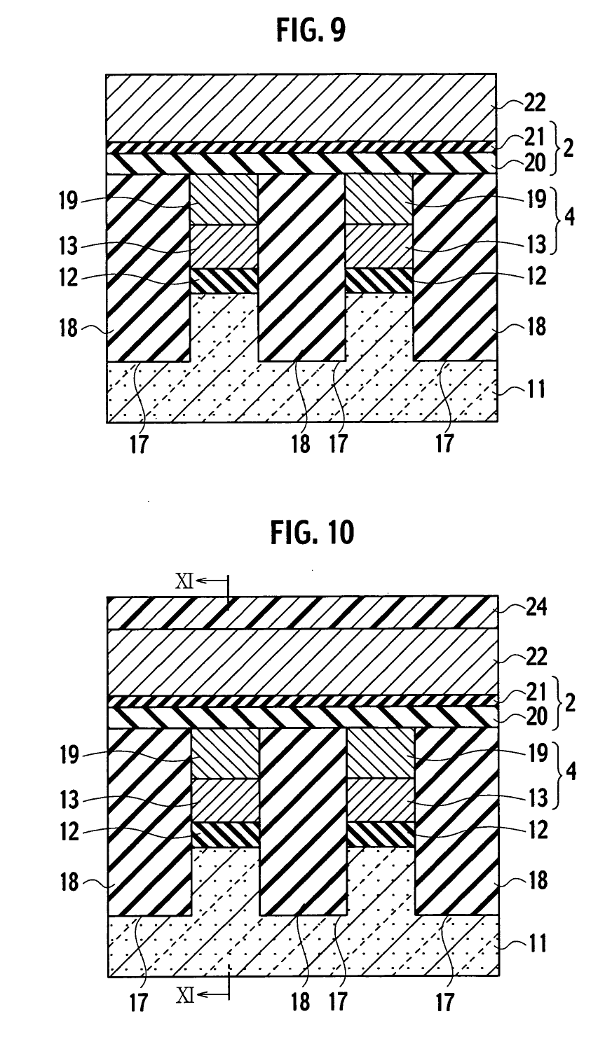

As shown in FIG. 9, the conductive layer 22 is deposited on the Al₂O₃ film 21. The conductive layer 22 serves as a control gate electrode in the non-volatile semiconductor storage device 1. For the conductive layer 22, a doped poly-Si film may be used. The poly-Si film is deposited with a thickness of about 10 nm to about 200 nm by CVD and the like.

When the poly-Si film is deposited by CVD, a silane (SiH₄) gas may be used as a source gas. As a result, the interior atmosphere of a vacuum chamber of a CVD apparatus becomes a SiH₄ reducing atmosphere. If there are O atoms bonded to Hf atoms on an exposed surface of a film above the substrate 11, hydrogen radicals in the SiH₄ reducing atmosphere may extract the O atoms.

When the surface of the HfAlO high dielectric constant insulating film 20 is exposed in the SiH₄ reducing atmosphere, the O atoms bonded to the Hf atoms in the exposed surface of the HfAlO high dielectric constant insulating film 20 are extracted. Therefore, it is understood that a leak current through the first high dielectric constant insulating film 20 may occur due to oxygen deficiency in the first high dielectric constant insulating film 20.

On the contrary, the hydrogen radicals in the SiH₄ reducing atmosphere cannot extract the exposed O atoms bonded to Al atoms. Therefore, the hydrogen radicals cannot extract the O atoms from the exposed Al₂O₃ film 21. Since the HfAlO high dielectric constant insulating film 20 is located deeper than the exposed surface of the Al₂O₃ film 21, the hydrogen radicals cannot extract the O atoms in the HfAlO high dielectric constant insulating film 20. Thus, it is possible to reduce a leak current due to oxygen deficiency in the first high dielectric constant insulating film 20.

The oxygen deficiency in the first high dielectric constant insulating film 20 may occur due to the reducing atmosphere during CVD of the poly-Si film as the conductive film 22. Thus, it is also effective to cover the surface of the first high dielectric constant insulating film 20 by the Al₂O₃ film 21 for reducing a leak current due to oxygen deficiency, when depositing the conductive film 22 using another source gas that provide a reducing atmosphere. For example, when titanium nitride (TiN) film is used as the conductive film 22 by CVD, source gases that provide a reducing atmosphere, such as titanium tetrachloride (TiCl₄) and ammonia (NH₃), may be used, and oxygen deficiency in the first high dielectric constant insulating film 20 may be suppressed by using the Al₂O₃ film 21 to cover the surface of the first high dielectric constant insulating film 20.

A HfAlO film, instead a hafnia (HfO) film, is used for the first high dielectric constant insulating film 20, even though the dielectric constant of HfAlO is less than that of HfO. This is because a HfAlO film has a good surface morphology compared with a HfO film. In the HfO film, when a thickness of the HfO film is decreased, the surface morphology of the HfO film is deteriorated. Thus, even if the Al₂O₃ film 21 is deposited on the HfO film, pin holes and the like are generated in the Al₂O₃ film 21. Consequently, it is difficult to obtain an Al₂O₃ film having a uniform thickness as a diffusion barrier film against the hydrogen radicals and the O atoms. On the contrary, it is possible to provide a high dielectric constant insulating film having a uniform thickness using the HfAlO film, in which about 5% or more of AlO is added to HfO. Therefore, the Al₂O₃ film 21 deposited on the HfAlO high dielectric constant insulating film 20, may also have a uniform thickness, and can be an effective diffusion barrier film against the hydrogen radicals and the O atoms.

The Al₂O₃ film 21 is suitable as the diffusion barrier film against the hydrogen radicals and the O atoms. This is because the Al₂O₃ film 21 can also be deposited in the oxidizing atmosphere just like the first high dielectric constant insulating film 20. For a diffusion barrier film, a Si₃N₄ film and the like can be used. However, since the Si₃N₄ film is deposited in the reducing atmosphere, the first high dielectric constant insulating film 20 may be damaged when depositing the Si₃N₄ film. Since the Al₂O₃ film 21 can be deposited in the oxidizing atmosphere, damage to the first high dielectric constant insulating film 20 can be suppressed. Moreover, the Al and O atoms in the Al₂O₃ film 21 are constituent elements of the first high dielectric constant insulating film 20. Thus, there is also an advantage that the diffusion barrier film may be deposited immediately after the first high dielectric constant insulating film 20 has been deposited.

Furthermore, in the NAND-type EEPROM, there may be a case where the sidewalls of a floating gate electrode are oxidized. By using the HfAlO high dielectric constant insulating film 20 together with the Al₂O₃ film 21, which serves as a diffusion barrier, for the IPD film 2, it is possible to prevent reduction of capacitance of the IPD film 2 by oxidation of Si atoms of the conductive layer 22 at an interface between the first high dielectric constant insulating film 20 and the conductive layer 22 during a sidewall oxidation process for the floating gate electrode 4. O atoms easily diffuse in the HfAlO high dielectric constant insulating film 20. Therefore, if the conductive layer 22 is provided on the first high dielectric constant insulating film 20 without the Al₂O₃ film 21, the conductive layer 22 may be oxidized to form a SiO₂film inthe interface between the first high dielectric constant insulating film 20 and the conductive layer 22. However, when the Al₂O₃ film 21 is provided between the HfAlO high dielectric constant insulating film 20 and the conductive layer 22, the Al₂O₃ film 21 prevents diffusion of the O atoms into the conductive layer 22. Accordingly, it is possible to prevent formation of a SiO₂ film, and the IPD film 2 having a high dielectric constant can be finally obtained.

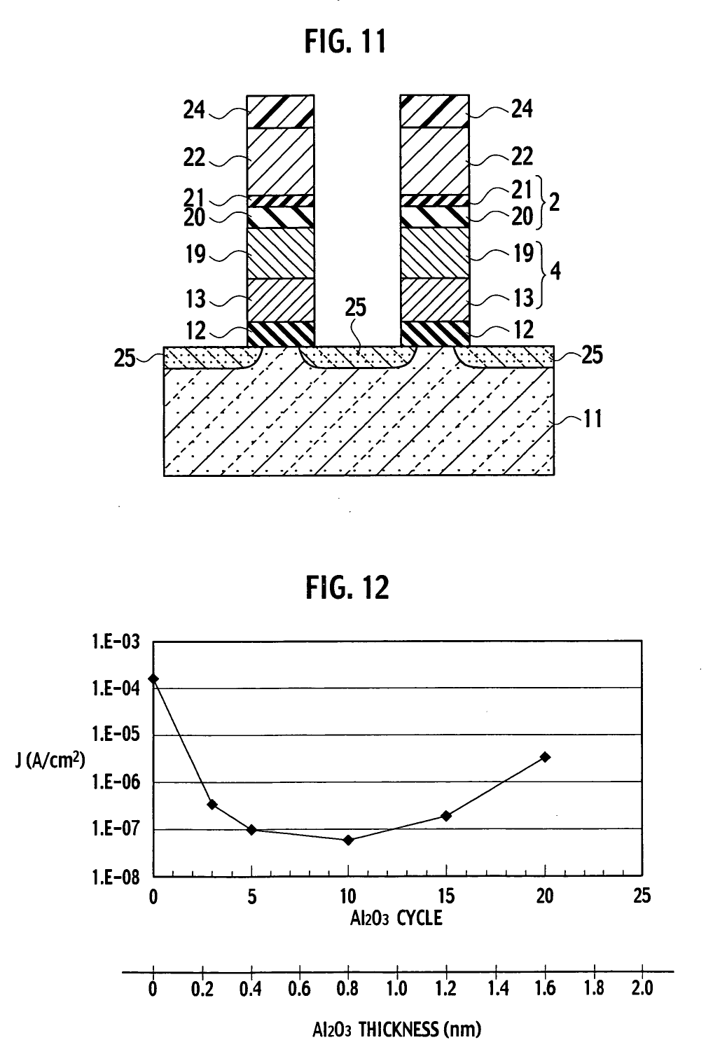

As shown in FIGS. 10 and 11, a resist film is coated onto the conductive layer 22. The resist film is patterned to a pattern of a control gate electrode by photolithography and the like. Thus, a resist pattern 24 is delineated. The conductive layer 22, the Al₂O₃ film 21, the first high dielectric constant insulating film 20, the second conductive film 19, the first conductive film 13, and the first insulating layer 12 are selectively removed by RIE and the like, using the resist pattern 24 as a mask.

For example, the conductive layer 22 is selectively removed using the Al₂O₃ film 21 as a stopper. The Al₂O₃ film 21 and the first high dielectric constant insulating film 20 are selectively removed using the second conductive film 19 as a stopper. The second conductive film 19 and the first conductive film 13 are selectively removed using the first insulating layer 12 as a stopper. The first insulating layer 12 is selectively removed using the substrate 11 as a stopper. A laminated structure including the conductive layer 22, the Al₂O₃ film 21, the first high dielectric constant insulating film 20, the second conductive film 19, the first conductive film 13, and the first insulating layer 12 is referred to a gate structure.

Using the gate structures as a self-align mask, n-type impurities are introduced by ion implantation from the surface of the Si substrate 11 exposed between the gate structures. Thereafter, the resist pattern 24 is removed. Subsequently, the implanted impurities are activated by activation annealing to form source/drain regions 25 in the Si substrate 11. Accordingly, a plurality of memory cells, each including the gate structures and the source/drain regions 25, disposed on both sides of the gate structures, can be formed.

As shown in FIGS. 1 to 3, an insulating layer 29, which serves as a passivation film, is deposited on the conductive layer 22 and the source/drain regions 25 by CVD and the like. For the insulating layer 29, a laminated film including a SiO₂ film and a Si₃N₄ film may be used.

Hence, the method of manufacturing the non-volatile semiconductor storage device 1 according to the first embodiment is complete.

A leak current of the non-volatile semiconductor storage device 1, manufactured by the foregoing manufacturing method, has been measured. For example, a voltage is applied between the floating gate electrode 4 and the control gate electrode (conductive layer) 22 so that electric field strength in the first high dielectric constant insulating film 20 is about 300 MV/m. Thus, a leak current density flowing in the thickness direction through the first high dielectric constant insulating film 20 can be measured.

As a result of the measurement, as shown in FIG. 12, the leak current density J of the non-volatile semiconductor storage device of the comparative example, in which the Al₂O₃ film 21 is omitted, is about two A/m². In the non-volatile semiconductor storage device 1 according to the first embodiment, when the alternate feeding cycles of TMA and O₃ for ALD of the Al₂O₃ film 21 is three, five, ten, fifteen, and twenty, the thickness of the Al₂O₃ film 21 is about 0.2 nm, about 0.4 nm, about 0.8 nm, about 1.2 nm, and about 1.6 nm, respectively, and the leak current density J is about 3×10⁻³ A/m², about 1×10⁻³ A/m², about 8×10^{31 4} A/m², about 2×10⁻³ A/m², and about 5×10⁻² A/m², respectively.

As described above, by providing the Al₂O₃ film 21, the leak current density J can be reduced compared with the comparative example. Specifically, the leak current density J can be reduced to about 1/40 or less compared with the comparative example, by providing the number of alternate feeding of TMA and O₃ in ALD for the Al₂O₃ film 21 within a range of 3 to 20 cycles, or by providing the thickness of the Al₂O₃ film 21 within a range of about 0.2 nm to about 1.6 nm.

Furthermore, the leak current density J can be reduced to about 1/100 or less compared with the comparative example by providing the number of alternate feeding of TMA and O₃ in ALD for the Al₂O₃ film 21 within a range of 5 to 15 cycles, or by providing the thickness of the Al₂O₃ film 21 within a range of about 0.4 nm to about 1.2 nm.

Particularly, the leak current density can be reduced to about 1/200 or less compared with the comparative example by providing the number of alternate feeding of TMA and O₃ in ALD for the Al₂O₃ film 21 of 10 cycles, or by providing the thickness of the Al₂O₃ film 21 of about 0.8 nm.

Moreover, in the first embodiment, descriptions have been given for the case where the poly-Si film is used for the conductive layer 22. However, it has been confirmed that the effect of reducing the leak current density is achieved also when a metal film, such as titanium (Ti), or a metal nitride film, such as titanium nitride (TiN), is used for the conductive layer 22.

In the first embodiment, when the HfAlO high dielectric constant insulating film 20 is used in the IPD film 2, the leak current can be reduced by introducing the Al₂O₃ film 21 only between the poly-Si film of the conductive layer 22 above the HfAlO high dielectric constant insulating film 20 and the HfAlO high dielectric constant insulating film 20. Details thereof will be described below.

A HfAlO film used for the first high dielectric constant insulating film 20 has a dielectric constant of about 10 to about 25. The more the concentration of Hf in the film is increased, the more the dielectric constant is increased. Therefore, for a condition of the same capacitance of the IPD film 2, a thickness of the first high dielectric constant insulating film 20 can be increased by increasing the concentration of Hf in the high dielectric constant insulating film. As a result, it is possible to reduce the leak current through the first high dielectric constant insulating film 20.

However, the free energy of HfO₂, which is about −253 Kcal/mol, is smaller than the free energy of Al₂O₃, which is about −378 Kcal/mol. Thus, a bonding strength between a Hf atom and an O atom in HfO₂ is smaller than a bonding strength between an Al atom and an O atom in Al₂O₃. In the reducing atmosphere, the O atoms bonded to the Hf atoms may be more easily extracted into the reducing atmosphere than the O atoms bonded to the Al atoms. When the HfAlO film is exposed in the reducing atmosphere, the higher the concentration of hafnium in the film, the more likely oxygen deficiency occurs. The oxygen deficiency causes an increase of the leak current through the first high dielectric constant insulating film 20.

As described above, in the HfAlO film, the increase of the dielectric constant and the reduction of the leak current are in a trade-off relationship. When the poly-Si conductive layer 22 is deposited without the Al₂O₃ film 21 after deposition of the HfAlO high dielectric constant insulating film 20, a leak current due to oxygen deficiency, which occurs in the SiH₄ reducing atmosphere during poly-Si CVD, may be increased together with an increase of the Hf concentration in the HfAlO high dielectric constant insulating film 20.

This is because the concentration of the O atoms bonded to the Hf atoms in the HfAlO high dielectric constant insulating film 20 is increased together with the increase in the Hf concentration in the HfAlO high dielectric constant insulating film 20. Thus, after the HfAlO high dielectric constant insulating film 20 has been deposited, the Al₂O₃ film 21 is deposited on the HfAlO high dielectric constant insulating film 20 before deposition of the poly-Si conductive layer 22.

The surface of the first high dielectric constant insulating film 20 is covered with the Al atoms and the O atoms bonded to the Al atoms. Since the Hf atoms and the O atoms bonded to the Hf atoms are not exposed in the reducing atmosphere, the O atoms may not be extracted from the first high dielectric constant insulating film 20. In the first high dielectric constant insulating film 20 covered with the Al₂O₃ film 21, the oxygen deficiency does not occur in the SiH₄ reducing atmosphere. Thus, an increase in the leak current can be suppressed.

Note that, as shown in FIG.12, when the thickness of the Al₂O₃ film 21 has been increased to about 0.8 nm, about 1.2 nm and about 1.6 nm, the leak current density J has been increased. A dielectric constant of the Al₂O₃ film 21, which is about 8 to about 10, is smaller than the dielectric constant of the HfAlO film 20, which is about 10 to about 25. When the thickness of the Al₂O₃ film 21 is increased, it is necessary to decrease the thickness of the first high dielectric constant insulating film 20 in order to retain the same IPD film capacitance. As a result, with the same electric field strength, the leak current density J is increased.

As described above, although the Al₂O₃ film 21 is necessary for reducing the leak current, it is understood that, when the Al₂O₃ film is too thick, the leak current is increased. Therefore, there is an optimum thickness for effectively reducing the leak current.

As shown in FIG. 12, the optimum thickness of the Al₂O₃ film 21 is within a range of about 0.2 nm to about 1.6 nm, and the leak current density can be reduced to about 1/40 of the comparative example. More desirably, the optimum thickness of the Al₂O₃ film 21 is within a range of about 0.4 nm to about 1.2 nm, and the leak current can be reduced to about 1/100 or less of the comparative example.

Since the Al₂O₃ film 21 is deposited by ALD, the number of alternate feeding cycles of the source gases of TMA and O₃, is in a one-on-one relation with the thickness of the Al₂O₃ film 21. Specifically, the optimum thickness can be determined with the optimum number of alternate feeding cycles. Thus, the desirable number of alternate feeding is about three to about twenty cycles, and more desirably, about five to about fifteen cycles.

As described above, according to the first embodiment, it is possible to provide a semiconductor device having a high dielectric constant insulating film capable of effectively suppressing a leak current.

(Second Embodiment)

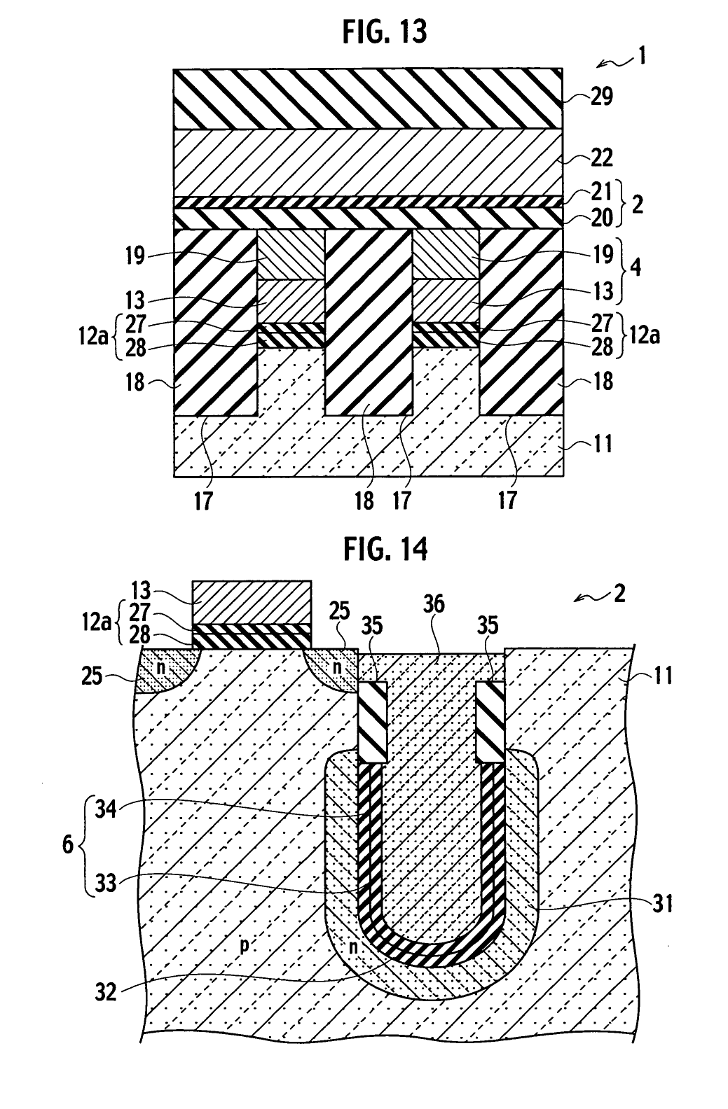

A semiconductor device according to a second embodiment of the present invention is also a non-volatile semiconductor storage device 1 such as a NAND-type EEPROM, as shown in FIG. 13. In the non-volatile semiconductor storage device 1 according to the second embodiment, the first high dielectric constant insulating film 20 is used not only in the IPD film 2, but also in a first gate insulating film 12a formed between the substrate 11 and the control gate electrode 4, which serves as a charge storage layer.

The non-volatile semiconductor storage device 1 includes the Si substrate (semiconductor region) 11, a first high dielectric constant insulating film 28 on the substrate 11, a second high dielectric constant insulating film (an Al₂O₃ film) 27 on the high dielectric constant insulating film 28, a first conductive film 13 on the Al₂O₃ film 27, and a conductive film 19 on the conductive film 13. Consequently, it is possible to reduce a leak current flowing between the substrate (semiconductor region) 11 and the first and second conductive films (conductive layer) 13, 19 through the high dielectric constant insulating film 28.

The non-volatile semiconductor storage device 1 according to the second embodiment differs from the first embodiment in that the first gate insulating film 12a has a laminated structure including the first high dielectric constant insulating film 28 as a lower film and the Al₂O₃ film 27 as an upper film. The other configurations are similar to the first embodiment. Thus, duplicated descriptions are omitted.

For the high dielectric constant insulating film 28, a composite oxide containing Al, such as HfAlO, ZrAlO, LaAlO, may be used.

A manufacturing method of the non-volatile semiconductor storage device 1 according to the second embodiment differs from the first embodiment only in a deposition method of the first gate insulating film 12a. For a deposition method of the first gate insulating film 12a according to the second embodiment, the deposition methods of the first high dielectric constant insulating film 20 and the Al₂O₃ film 21, including PDA, according to first embodiment, are used. Moreover, desired thicknesses of the high dielectric constant insulating film 28 and the Al₂O₃ film 27 are provided by adjusting the number of alternate feeding cycles of the source gases as needed.

Furthermore, the same effect of reducing the leak current, as shown in FIG. 12, is also achieved for the first gate insulating film 12a.

As described above, according to the second embodiment, it is possible to provide a semiconductor device having a high dielectric constant insulating film capable of effectively suppressing a leak current.

(Third Embodiment)

As shown in FIG. 14, a semiconductor device according to a third embodiment of the present invention is a volatile semiconductor storage device 2, such as a dynamic random access memory (DRAM). In the volatile semiconductor storage device 2 according to the third embodiment, first and second high dielectric constant insulating films 33, 34 are used in a capacitor insulating film 6, and a first and second high dielectric constant insulating films 28, 27 are used in a gate insulating film 12a of a select transistor.

The volatile semiconductor storage device 2 includes a semiconductor region (a plate electrode) 31, the first high dielectric constant insulating film 33, the second high dielectric constant insulating film (an Al₂O₃ film) 34, and a conductive layer (a storage electrode) 36. The first high dielectric constant insulating film 33 is provided on the semiconductor region 31. The Al₂O₃ film 34 is provided on the first high dielectric constant insulating film 33. The conductive layer 36 is provided on the Al₂O₃ film 34. Consequently, it is possible to reduce a leak current flowing between the semiconductor region 31 and the conductive layer 36 through the first high dielectric constant insulating film 33.

Furthermore, the volatile semiconductor storage device 2 includes a semiconductor region (a Si substrate) 11, the first high dielectric constant insulating film 28, the second high dielectric constant insulating film (an Al₂O₃ film) 27, and a conductive layer (a gate electrode) 13. The first high dielectric constant insulating film 28 is provided on the semiconductor region 11. The Al₂O₃ film 27 is provided on the first high dielectric constant insulating film 28. The conductive layer 13 is provided on the Al₂O₃ film 27. Consequently, it is possible to reduce a leak current flowing between the semiconductor region 11 and the conductive layer 13 through the first high dielectric constant insulating film 28.

As described above, the volatile semiconductor storage device 2 includes the substrate 11, the plate electrode 31, the first high dielectric constant insulating film 33, the Al₂O₃ film 34, a collar oxide film 35, the storage electrode 36, source/drain regions 25, the first high dielectric constant insulating film 28, the Al₂O₃ film 27, and the gate electrode 13. The volatile semiconductor storage device 2 has a capacitor which includes the plate electrode 31, the capacitor insulating film 6, and storage electrode 36.

For the substrate 11, a p-type Si substrate may be used. The capacitor insulating film 6, which includes the first high dielectric constant insulating film 33 and the Al₂O₃ film 34, is provided in a deep trench 32 formed in the substrate 11.

Moreover, the volatile semiconductor storage device 2 has a select transistor which includes the source/drain regions 25, the gate insulating film 12a, and the gate electrode 13. The gate insulating film 12a includes the first high dielectric constant insulating film 28 and the Al₂O₃ film 27. The source/drain regions 25 are connected to the storage electrode 36 of the capacitor.

The plate electrode 31 is a Si single crystal. The plate electrode 31 has ann-type conductivity, which is different from the p-type Si substrate 11. The plate electrode 31 is provided in a surface region of the deep trench 32. The capacitor insulating film 6 is provided between the plate electrode 31 and the storage electrode 36. The first high dielectric constant insulating film 33 is provided on the plate electrode 31. For the first high dielectric constant insulating film 33, a composite oxide containing Al, such as HfAlO, ZrAlO, LaAlO, may be used. The storage electrode 36 is provided on the Al₂O₃ film 34, so as to fill in the deep trench 32. The storage electrode 36 is n-type poly-Si or the like.

The collar oxide film 35 is provided on an edge of the capacitor insulating film 6 in the deep trench 32. The collar oxide film 35 serves as an electrical isolation film for preventing a parasitic transistor from turning on between the plate electrode 31 and the source/drain regions 25.

The source/drain regions 25 are formed in the substrate 11 including a surface of the substrate 11. The source/drain regions 25 are impurity diffusion layers.

The gate insulating film 12a is provided on the substrate 11. The gate insulating film 12a has a laminated structure including the first high dielectric constant insulating film 28 as a lower film and the Al₂O₃ film 27 as an upper film. For the first high dielectric constant insulating film 28, a composite oxide containing Al, such as HfAlO, ZrAlO, LaAlO, may be used. For the gate electrode 13, a conductive film, such as n-type poly-Si, may be used.

The volatile semiconductor storage device 2 according to the third embodiment is basically manufactured by a method similar to a usual manufacturing method of a volatile semiconductor storage device. However, a manufacturing method of a volatile semiconductor storage device 2 according to the third embodiment differs from the usual manufacturing method of a volatile semiconductor storage device in deposition methods for the capacitor insulating film 6 and the gate insulating film 12a.

For the deposition methods of the capacitor insulating film 6 and the gate insulating film 12a according to the third embodiment, the deposition methods of the first high dielectric constant insulating film 20 and the Al₂O₃ film 21, including PDA, according to the first embodiment, are used. Thus, the first high dielectric constant insulating films 28 and 33, and the Al₂O₃ films 27 and 34 are deposited, respectively. Moreover, desired thicknesses of the first high dielectric constant insulating films 28, 33 and the Al₂O₃ films 27, 34 are provided by adjusting the number of alternate feeding cycles of the source gases as needed.

The same effect of reducing the leak current as shown in FIG. 12 is also achieved for the capacitor insulating film 6 of the volatile semiconductor storage device 2. Moreover, the same effect of reducing the leak current as shown in FIG. 12 is also achieved for the first gate insulating film 12a of the volatile semiconductor storage device 2. Thus, it is possible to achieve a good device characteristic for the volatile semiconductor storage device 2 compared with a current volatile semiconductor storage device.

As described above, according to the third embodiment, it is possible to provide a semiconductor device having a high dielectric constant insulating film capable of effectively suppressing a leak current.

(Other Embodiments)

The present invention has been described through the first to third embodiments as mentioned above. However the descriptions and drawings that constitute a portion of this disclosure should not be perceived as limiting this invention. Various alternative embodiments and operational techniques will become clear to persons skilled in the art from this disclosure.

Accordingly, the present invention naturally includes various embodiments not specifically mentioned herein. Accordingly, the technical scope of the present invention may be limited only by the inventive features set forth by the scope of the patent claims deemed reasonable from the above description.

What is claimed is:

1. A semiconductor device, comprising:
a semiconductor region;
a first high dielectric constant insulating film provided on the semiconductor region, the first high dielectric constant insulating film being a film other than alumina;
a second high dielectric constant insulating film provided on the first high dielectric constant insulating film, the second high dielectric constant insulating film being an alumina film; and
a conductive layer provided on the second high dielectric constant insulating film.

2. The semiconductor device of claim 1, wherein the first high dielectric constant insulating film is a composite oxide containing hafnium and aluminum.

3. The semiconductor device of claim 1, wherein the thickness of the second high dielectric constant insulating film is in a range of about 0.2 nm to about 1.6nm.

4. The semiconductor device of claim 1, wherein the conductive layer is polysilicon.

5. The semiconductor device of claim 1, wherein the semiconductor region is polysilicon.

6. The semiconductor device of claim 1, wherein the semiconductor region is a single crystal silicon.

7. The semiconductor device of claim 1, wherein the first and second high dielectric constant insulating films implement an inter-electrode insulating film between the semiconductor region and the conductive layer, the semiconductor region and the conductive layer being a floating gate electrode and a control gate electrode of a non-volatile memory, respectively.

8. The semiconductor device of claim 1, wherein the first and second high dielectric constant insulating films implement a gate insulating film.

9. The semiconductor device of claim 1, wherein the first and second high dielectric constant insulating films implement a capacitor insulating film of a dynamic random access memory.

10. A method for manufacturing a semiconductor device, comprising:
depositing a first high dielectric constant insulating film on a semiconductor region, the first high dielectric constant insulating film being a film other than alumina;
depositing a second high dielectric constant insulating film on the first high dielectric constant insulating film, the second high dielectric constant insulating film being an alumina film;
anneal the second high dielectric constant insulating film; and
depositing a conductive layer on the second high dielectric constant insulating film in a reducing atmosphere.

11. The method of claim 10, wherein deposition of the second high dielectric constant insulating film including:
sequentially and repeatedly executing a plurality of cycles, each of the cycle including:
introducing an aluminum compound so as to provide reactive species adsorbed on a surface of the high dielectric constant insulating film, the reactive species being molecules of the aluminum compound or decomposed molecules of the aluminum compound; and
introducing an oxidant gas to the surface of the high dielectric constant insulating film so as to react the oxidant gas to the adsorbed reactive species.

12. The method of claim 10, wherein the first high dielectric constant insulating film is a composite oxide containing hafnium and aluminum.

13. The method of claim 10, wherein the thickness of the second high dielectric constant insulating film is in a range of about 0.2 nm to about 1.6 nm.

14. The method of claim 10, wherein the conductive layer is deposited by using a silane gas as a source gas.

15. The method of claim 10, wherein the conductive layer is polysilicon.

16. The method of claim 10, wherein the semiconductor region is polysilicon.

17. The method of claim 10, wherein the semiconductor region is a single crystal silicon.

18. The method of claim 10, further comprising:
annealing the first high dielectric constant insulating film before depositing the second high dielectric constant insulating film.

19. The method of claim 11, wherein the plurality of the cycles are in a range of from about three to about twenty cycles.

20. The method of claim 12, wherein deposition of the second high dielectric constant insulating film including:
sequentially and repeatedly executing a plurality of sequences, each of the sequence including:
sequentially and repeatedly executing a plurality of cycles, each of the cycle includes:
introducing a hafnium compound so as to adsorb first reactive species on a surface of the semiconductor region, the first reactive species being molecules of the hafnium compound or decomposed molecules of the hafnium compound; and
introducing an oxidant gas to the surface of the semiconductor region so as to react the oxidant gas to the adsorbed first reactive species; and
sequentially and repeatedly executing a cycle includes:
introducing an aluminum compound so as to adsorb second reactive species on the processing surface of the semiconductor region, the second reactive species being molecules of the aluminum compound or decomposed molecules of the aluminum compound; and
introducing the oxidant gas to the processing surface of the semiconductor region so as to react the oxidant gas to the adsorbed second reactive species.
